(19) United States
(12) Patent Application Publication
(10) Pub. No.: US 2025/0329513 A1
(43) Pub. Date: Oct. 23, 2025

(54) INDUCTIVELY-COUPLED PLASMA ANTENNAS FOR SEMICONDUCTOR WAFER PROCESSING SYSTEMS

(71) Applicant: Samsung Electronics Co., Ltd., Suwon-si (KR)

(72) Inventors: Sungyoung Yoon, Suwon-si (KR); Sungyeol Kim, Suwon-si (KR); Meehyun Lim, Suwon-si (KR); Kyungsun Kim, Suwon-si (KR); Donghyeon Na, Suwon-si (KR); Sungyong Lim, Suwon-si (KR); Sanghoon Jung, Suwon-si (KR); Yongwon Cho, Suwon-si (KR)

(21) Appl. No.: 19/010,874

(22) Filed: Jan. 6, 2025

(30) Foreign Application Priority Data
Apr. 17, 2024 (KR) 10-2024-0051687

(51) Int. Cl. H01J 37/32

(52) U.S. Cl. CPC H01J 37/3211; H01J 37/32651

(57) ABSTRACT

An inductively coupled plasma antenna, which is configured for use in a semiconductor wafer processing apparatus, includes: a plurality of loop-shaped coil portions extending adjacent to each other in sequence, said plurality of loop-shaped coil portions including at least a first loop-shaped coil portion and a second loop-shaped coil portion, and a high-frequency power source configured to supply high-frequency current to each of the plurality of loop-shaped coil portions, such that respective high-frequency currents flow in opposite directions in adjacent and facing lines of the first loop-shaped coil portion and the second loop-shaped coil portion.

### REFERENCE TO PRIORITY APPLICATION

This application claims the benefit under 35 USC 119(a) of Korean Patent Application No. 10-2024-0051687, filed Apr. 17, 2024, the disclosure of which is hereby incorporated herein by reference.

### BACKGROUND

The present inventive concept relates to an inductively coupled plasma antenna and a semiconductor wafer processing apparatus including an inductively coupled plasma antenna.

Among semiconductor processes for manufacturing semiconductor devices, a semiconductor wafer processing apparatus using plasma processing may perform etching, physical vapor deposition (PVD), chemical vapor deposition (CVD), resist removal deposition processes, and the like.

Recently, in the high aspect ratio contacts (HARCs) etching process, which is being carried out due to the demand for higher integration of semiconductor substrates, the power level has become complex and multi-staged in accordance with the demand for advancement of the critical dimension. Additionally, there is a trend of increasing high-end frequencies to increase the yield of semiconductor substrates.

The plasma generation method for such plasma processing generally uses an inductively coupled plasma (ICP) method. The inductively coupled plasma method forms a magnetic field that changes temporally in a direction perpendicular to the plane formed by the antenna coil as radio frequency (RF) power is provided to the antenna coil, and thus, electrons in the semiconductor wafer processing chamber are heated to generate a plasma. In the inductively coupled plasma method, a matcher is connected between the high-frequency power source that provides high-frequency power and the antenna coil. The matcher facilitates power transfer, but also causes power loss and reduces power transfer speed.

Research is needed on inductively coupled antennas that have no problems with power transfer between antenna coils from high-frequency power sources regardless of the use of a matcher and may increase power transfer speed.

Additionally, inductively coupled plasmas have been induced by increasing the frequency of an antenna. When the frequency is increased, the voltage of the inductively coupled antenna also increases. When the voltage of the antenna increases, the ions of a plasma generated within the semiconductor device and the attractive force act, causing the plasma ions to hit the wall of the process chamber of the semiconductor wafer processing apparatus. And, when plasma ions hit the upper wall of the process chamber, particles are generated from the upper wall of the process chamber and fall on the semiconductor wafer being processed, causing particle contamination on the semiconductor wafer.

Thus, there is a need for the development of inductively coupled plasma antenna technology that may remove particle contamination on wafers while increasing frequency.

### SUMMARY

Example embodiments provide an inductively coupled plasma antenna having improved power loss and speed problems without using a matcher.

Example embodiments provide an inductively coupled plasma antenna that may reduce antenna inductance even when high-frequency power is applied, thereby reducing antenna voltage and inhibiting particle contamination on a wafer.

Example embodiments provide a semiconductor wafer processing apparatus including an inductively coupled plasma antenna capable of removing particle contamination from a wafer.

According to example embodiments, an inductively coupled plasma antenna, which is configured for use in a semiconductor wafer processing apparatus, includes a plurality of loop-shaped coil portions, which extend adjacent to each other in sequence. The plurality of loop-shaped coil portions include at least a first loop-shaped coil portion and a second loop-shaped coil portion. A high-frequency power source is also provided, and is configured to supply high-frequency current to each of the plurality of loop-shaped coil portions, such that respective high-frequency currents flow in opposite directions in adjacent and facing lines of the first loop-shaped coil portion and the second loop-shaped coil portion.

According to further example embodiments, an inductively coupled plasma antenna applied to a semiconductor wafer processing apparatus includes a first loop coil portion comprised of a first line through which high-frequency current flows, a second line through which the high-frequency current flows and generates a plasma, a third line which opposes the first line and through which the high-frequency current flows in a direction opposite to a direction of current through the first line, and a fourth line through which the high-frequency current flows in a direction opposite to a direction of current through the second line. A second loop coil portion is provided, which is disposed immediately adjacent at a fine interval from the first loop coil portion, and includes a first line through which high-frequency current flows, a second line through which the high-frequency current having passed through the first line flows and generates a plasma, a third line which opposes the first line and through which the high-frequency current flows in a direction opposite to a direction of current through the first line, and a fourth line through which the high-frequency current flows in a direction opposite to a direction of current through the second line. A high-frequency power source is provided, which supplies high-frequency current to the first loop coil portion and the second loop coil portion. A shielding portion is provided, which has a through-hole through which the first line of the first loop coil portion and the third line of the second loop coil portion penetrate. The shielding portion extends between the second line and the fourth line of each of the first loop coil portion and the second loop coil portion.

According to example embodiments, a semiconductor wafer processing apparatus includes a process chamber having an internal space therein, a lower electrode supporting a semiconductor wafer within the process chamber and an upper electrode facing the lower electrode and including a shower head supplying plasma gas. In addition, an inductively coupled plasma antenna is provided, which includes a segment coil portion in which a plurality of loop-shaped segment coils disposed on an upper portion of the upper electrode are adjacently disposed. The inductively coupled plasma antenna includes a high-frequency power source that is connected to each of the plurality of loop-shaped segment coils and individually supplies high-frequency current. The plurality of loop-shaped segment coils include a first loop coil portion and a second loop coil portion. The first loop coil portion and the second loop coil portion respectively include a first line through which the high-frequency current flows, a second line through which the high-frequency current having passed through the first line flows and generates a plasma, a third line through which the high-frequency current of which a direction has been changed through the second line flows, and a fourth line through which the high-frequency current flows in a direction opposite to a direction of current through the second line. The high-frequency current flowing through the first line of one of the first loop coil portion and the second loop coil portion and the high-frequency current flowing through the third line of the other, which faces the first line, flow in opposite directions.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic cross-sectional view of a semiconductor wafer processing apparatus according to an example embodiment;

FIG. 2 is a two-dimensional conceptual diagram of an inductively coupled plasma antenna applied to the semiconductor wafer processing apparatus of FIG. 1;

FIG. 3 is an enlarged view of highlighted region A in FIG. 2;

FIG. 4 is a three-dimensional conceptual diagram of an inductively coupled plasma antenna applied to the semiconductor wafer processing apparatus of FIG. 1;

FIG. 5 is a schematic perspective view illustrating a first embodiment of the inductively coupled plasma antenna of the present inventive concept;

FIG. 6 is a schematic perspective view illustrating a second embodiment of the inductively coupled plasma antenna of the present inventive concept;

FIG. 7 is a schematic perspective view illustrating a third embodiment of the inductively coupled plasma antenna of the present inventive concept;

FIG. 8 is a schematic diagram illustrating current flow according to the number of segments of an inductively coupled plasma antenna according to an example embodiment;

FIG. 9 is a graph illustrating results of antenna inductance versus antenna resistance measured according to the example embodiment of FIG. 8; and

FIG. 10 is a graph illustrating measurement results of current and voltage of an antenna measured according to the example embodiment of FIG. 8.

### DETAILED DESCRIPTION

Hereinafter, example embodiments will be described with reference to the accompanying drawings. These example embodiments of the present inventive concept may be modified to have various other forms, and are included herein to provide a more complete explanation to those skilled in the art. Accordingly, the shapes and sizes of elements in the drawings may be exaggerated for clear description, and elements indicated by the same symbol in the drawings refer to the same element.

In the present inventive concept, the meaning of “connection” is a concept including not only “directly connected” but also “indirectly connected” through other configurations. In the present inventive concept, expressions such as “first”, “second” and the like are used to distinguish one component from another component and do not limit the order and/or importance of the components. In some cases, the first component may be named the second component, and similarly, the second component may be named the first component without departing from the scope of rights.

The terminology used in the present inventive concept is used to describe examples only and is not intended to limit the present inventive concept. Moreover, singular expressions include plural expressions, unless the context clearly indicates otherwise.

### Semiconductor Wafer Processing Apparatus

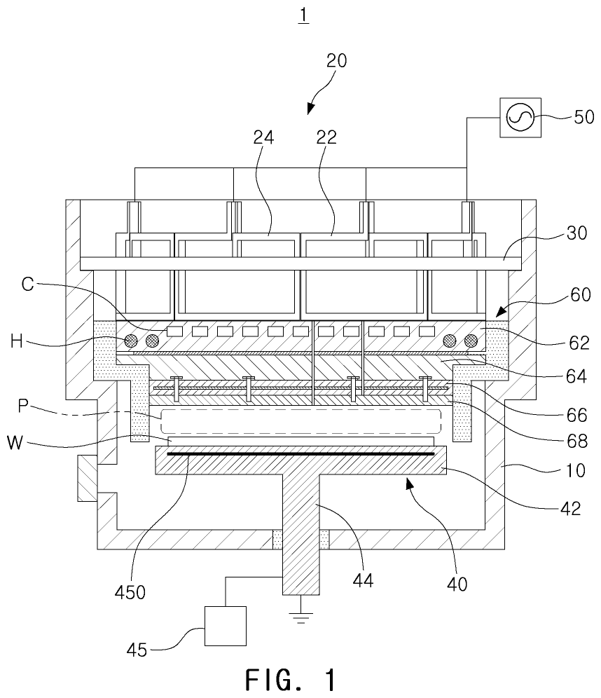

FIG. 1 is a schematic cross-sectional view of a semiconductor wafer processing apparatus according to an example embodiment. Referring to FIG. 1, a semiconductor processing apparatus 1 according to an example embodiment includes a process chamber 10, an upper electrode 60, and a lower electrode 40.

The process chamber 10 provides a space sealed from the outside for the semiconductor wafer W, and a process on the wafer W may be performed in the sealed space. The semiconductor process may include, for example, at least one of a deposition process, an etching process, and a cleaning process. In particular, an etching process may include an etching process associated with high aspect ratio contacts (HARCs), which are carried out in response to the demand for high integration of semiconductor substrates.

The process chamber 10 is formed of a metal material such as aluminum (Al), and in an example embodiment, the process chamber 10 may include a substrate passage through which the semiconductor wafer W is loaded or unloaded. The upper electrode 60 further includes shower heads 66 and 68 and upper plates 62 and 64. Shower heads 66 and 68 introduce process gas and discharge the process gas onto the semiconductor wafer W within the process chamber 10.

A gas distribution structure that supplies process gas to the shower heads 66 and 68 and a cooler C or heater (H) that may control the temperature of the shower heads 66 and 68 may be embedded in the upper plates 62 and 64. Additionally, an inductively coupled plasma antenna 20 that forms an electric field path inside the process chamber 10 may be disposed on the upper plates 62 and 64.

The lower electrode 40 includes an electrostatic chuck 42 supporting the semiconductor wafer W in the process chamber 10 and a lower supporter 44 supporting the electrostatic chuck 42. The electrostatic chuck 42 is a member that supports the semiconductor wafer W, and when the power supply unit 45 supplies power, the lower supporter 44 vertically rises or falls to adjust the distance from the shower heads 66 and 68.

The electrostatic chuck 42 may be a susceptor including a heating pattern, and the heating pattern may heat the susceptor using power supplied from an external power supply device 45. For example, the susceptor may be formed of a ceramic material such as aluminum nitride (AlN), aluminum oxide (Al₂O₃), or the like.

When power is supplied to the inductively coupled plasma antenna 20 from the high-frequency power source 50, high frequency current flows through the coil of the inductively coupled plasma antenna 20 and forms an electric field path inside the process chamber 10.

When plasma gas is ejected from the shower heads 66 and 68 and high frequencies are applied to the inductively coupled plasma antenna 20 and the lower electrode 40, the inductively coupled plasma antenna 20 as the upper electrode and the lower electrode 40 may interact to form a plasma P in the space between the upper wall of the process chamber 10 and the semiconductor wafer W.

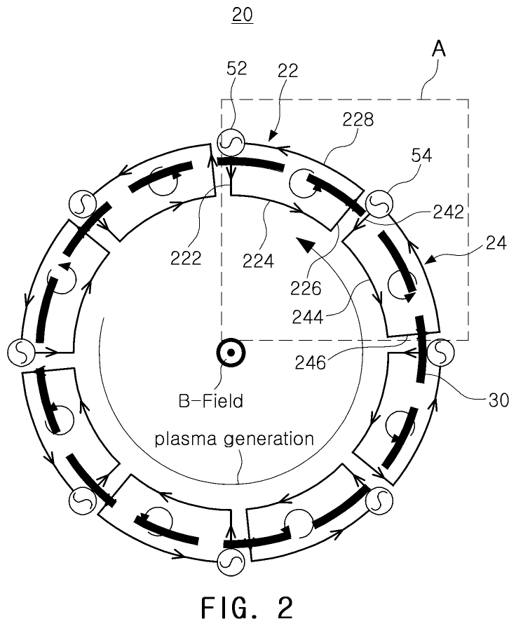

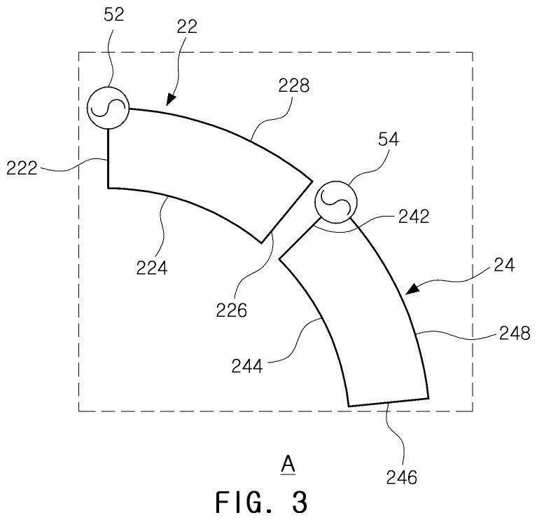

The structure and operation of the inductively coupled plasma antenna 20 will be described in detail. In particular, FIG. 2 is a two-dimensional conceptual diagram of an inductively coupled plasma antenna applied to the semiconductor wafer processing apparatus of FIG. 1, and FIG. 3 is an enlarged view of A of FIG. 2. Referring to FIGS. 2 and 3, the inductively coupled plasma antenna 20 according to an example embodiment includes a plurality of loop-shaped segment coil portions and a high-frequency power source 50. The plurality of loop-shaped segment coil portions includes a first loop coil portion 22 and a second loop coil portion 24. The segment coil portion may be composed of two or more segments.

The first loop coil portion 22 and the second loop coil portion 24 are respectively segment antennas and have a loop-type structure. If each segment coil portion is formed in a loop shape to form a magnetic field and induced electromagnetic force, the segment coil portion may be formed in various manners, such as single loop, multi-loop, quadrangle, circular, helical, and spiral shapes, without any particular restrictions.

The high-frequency power source 50 is connected to each of the first loop coil portion 22 and the second loop coil portion 24, and thus, high-frequency currents in opposite directions may flow in adjacent and facing lines of the first loop coil portion 22 and the second loop coil portion 24. In this case, a synchronization device that adjusts the shape of the high-frequency current may be connected to the high-frequency power source 50. The size of the induced magnetic field may be adjusted by varying the shape of the high-frequency current in each of the first loop coil portion 22 and the second loop coil portion 24 in the high-frequency power source 50. For example, the shape of the high-frequency current may include or be adjusted to have a sine wave shape in time, a sine wave with a different phase difference, a traveling sine wave in space, or the like. In this case, the first loop coil portion 22 and the second loop coil portion 24 include first lines 222 and 242, second lines 224 and 244, third lines 226 and 246, and fourth lines 228 and 248, respectively, and form a separate loop shape.

High-frequency current flows from the high-frequency power source 50 into the first lines 222 and 242 of the first loop coil portion 22 and the second loop coil portion 24. In addition, high frequency current from the first lines 222 and 242 flows through the second lines 224 and 244 of the first loop coil portion 22 and the second loop coil portion 24, and high-frequency current flowing through the second lines 224 and 244 of the first loop coil portion 22 and the second loop coil portion 24 generates a plasma.

In the third lines 226 and 246 of the first loop coil portion 22 and the second loop coil portion 24, high-frequency currents having passed through the second lines 224 and 244 flow in the directions opposite to the direction of currents through the first lines 222 and 242 of the adjacent loop coil portions. For example, the high-frequency current passing through the second line 224 of the first loop coil portion 22 changes direction and flows through the third line 226. The high frequency current flowing through the third line 226 of the first loop coil portion 22 flows in the opposite direction to the high frequency current flowing in the first line 242 of the second loop coil portion 24 adjacent to the first loop coil portion 22. Therefore, since the direction of the current flowing between the third line 226 of the adjacent first loop coil portion 22 and the first line 242 of the second loop coil portion 24 is different, the magnetic field is canceled between the third line 226 of the first loop coil portion 22 and the first line 242 of the second loop coil portion 24. In the fourth lines 228 and 248 of the first loop coil portion 22 and the second loop coil portion 24, the high-frequency current passing through the third lines 226 and 246 of respective coil portions 22 and 24 changes direction and flows.

Referring to FIG. 2, the high frequency current of the second lines 224 and 244 of the first loop coil portion 22 and the second loop coil portion 24 has a clockwise high-frequency current flow along with the second lines of the adjacent loop coil portion. Meanwhile, the high-frequency power sources 52 and 54 connected to the first lines 222 and 242 of respective loop coil portions 22 and 24 may switch the power to reverse the direction of the high-frequency current. Plasma generation within the process chamber 10 may be variably controlled by power switching.

The first lines 222 and 242 of the first loop coil portion 22 and the second loop coil portion 24 may be directly connected to independent high-frequency power sources 52 and 54, respectively. Additionally, each of the first lines 222 and 242 of the first loop coil portion 22 and the second loop coil portion 24 may be connected to a connection line branched from one high-frequency power source 50. The shielding portion 30 is located between the first lines 222 and 242 and the third lines 226 and 246, and interference of high-frequency currents of the second lines 224 and 244 and the fourth lines 228 and 248 may be shielded. In this case, the voltage of the inductively coupled plasma antenna may be controlled by adjusting the interference between the second lines 224 and 244 and the fourth lines 228 and 248.

Referring to FIGS. 1 to 3, the process that occurs in the process chamber 10 using the inductively coupled plasma antenna 20 will be described. First, the inside of the process chamber 10 is evacuated by a vacuum pump, and a reaction gas that generates a plasma is injected from the shower heads 66 and 68. The high-frequency power sources 52 and 54 provide high-frequency (RF) power to the first loop coil portion 22 and the second loop coil portion 24, respectively, and when high frequency power is provided, high-frequency currents flow in the first lines 222 and 242, second lines 224 and 244, third lines 226 and 246, and fourth lines 228 and 248 of the first loop coil portion 22 and the second loop coil portion 24, while forming individual loops.

As radio frequency (RF) power is provided, high frequency current flows clockwise through the second lines 224 and 244 of the loop coil of the inductively coupled plasma antenna 20, and a magnetic field (B-field) that changes temporally in a direction perpendicular to the plane of the second line flowing clockwise is formed. This magnetic field (B-field) induces an electric field (EMF) inside the process chamber 10, and the induced electric field heats electrons to generate a plasma. In this manner, electrons collide with surrounding neutral gas particles to generate ions and radicals, which are used for plasma etching and deposition.

When complex power supply and an increase in the frequency of high-frequency power are required, such as a high aspect ratio contact etching process that requires advanced critical dimensions, the voltage of the plasma antenna is increased, and the relational equation for antenna voltage is as follows:

$${V}_{ANTENNA} = I \cdot {R}_{ANTENNA} + {L}_{ANTENNA} \frac{dI}{dt} \qquad Equation ( 1 )$$

$$\frac{dI}{dt} = 2 π f \cdot I \qquad Equation ( 2 )$$

Referring to Equation (1), it can be seen that the antenna voltage V_{Antenna} is proportional to the product of the antenna current I and the antenna resistance R_{Antenna} and the product of the antenna inductance L_{Antenna} and the change in current over time. In addition, Equation (2) illustrates that the amount of change in current over time is proportional to the frequency f. From Equations (1) and (2), it can be seen that an increase in frequency increases the antenna voltage. When the antenna voltage increases, dissociated charges, electrons, etc. in the plasma region P within the process chamber 10 may move and hit the inductively coupled plasma antenna 20 and damage the upper inner wall of the process chamber 10 and the coating on the wall.

Therefore, in order to prevent the antenna voltage from becoming higher than necessary and maintain an appropriate voltage, a shielding portion 30 may be formed between the second lines 224 and 244 and the fourth lines 228 and 248. The second lines 224 and 244 forms a magnetic field that generates a plasma, and the fourth lines 228 and 248 has a high-frequency current flowing in the opposite direction to the direction of current through the second lines 224 and 244, and thus, inductance that occurs in the second lines 224 and 244 may be reduced. Thus, by reducing the inductance occurring in the second lines 224 and 244, the antenna voltage VA antenna may be lowered according to equation (1). In addition, a shielding portion 30 may be formed between the second lines 224 and 244 and the fourth lines 228 and 248 in order to maintain a voltage at which a plasma may be generated in the second lines 224 and 244.

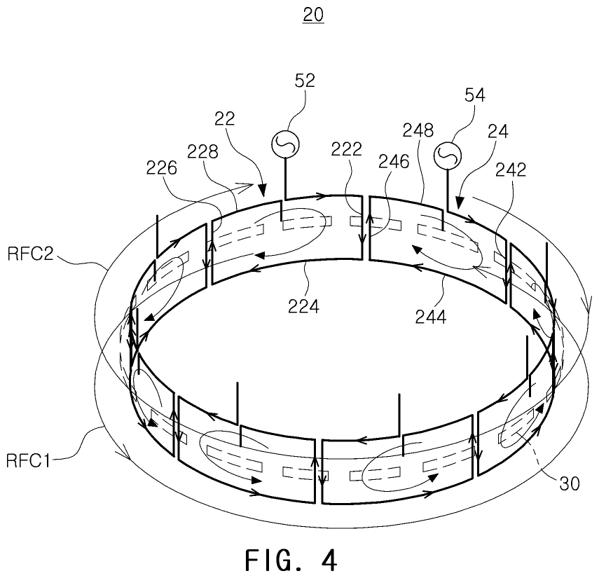

FIG. 4 is a three-dimensional conceptual diagram of an inductively coupled plasma antenna applied to the semiconductor wafer processing apparatus of FIG. 1. Looking at it in three dimensions, the high frequency current flowing in the first lines 222, 242 and the third lines 226, 246 of the adjacent first loop coil portion 22 and the second loop coil portion 24 flows in an upward and downward direction to cancel out the magnetic field. In this embodiment, the high-frequency current RFC1 flowing through the second lines 224 and 244 flows counterclockwise, and the high-frequency current RFC2 flowing through the fourth lines 228 and 248 flows clockwise. The second lines 224 and 244 of the first loop coil portion 22 and the second loop coil portion 24 are located below close to the wafer W in the drawings of FIGS. 1 and 4 when viewed in a three-dimensional plane, and electromagnetic force (EMF) that generates a plasma is generated.

In the drawings of FIGS. 1 and 4, the fourth lines 228 and 248 located above the second lines 224 and 244 of the first loop coil portion 22 and the second loop coil portion 24 generate mutual inductance that reduces the inductance occurring in the second lines 224 and 244. By reducing the inductance occurring in the second lines 224 and 244, the antenna voltage V_{Antenna} may be lowered according to Equation (1). In addition, a shielding portion 30 may be formed between the second lines 224 and 244 and the fourth lines 228 and 248 in order to maintain a voltage at which a plasma may be generated in the second lines 224 and 244. By installing the shielding portion 30, the antenna voltage V_{Antenna} is properly maintained even when a plasma P is generated in the second lines 224 and 244 even when a high frequency voltage is provided. Therefore, it is possible to reduce the phenomenon of charges or electrons dissociated from the plasma P moving to the upper wall of the process chamber 10 and striking them. Therefore, the phenomenon of contamination by particles falling on the semiconductor wafer W may be reduced.

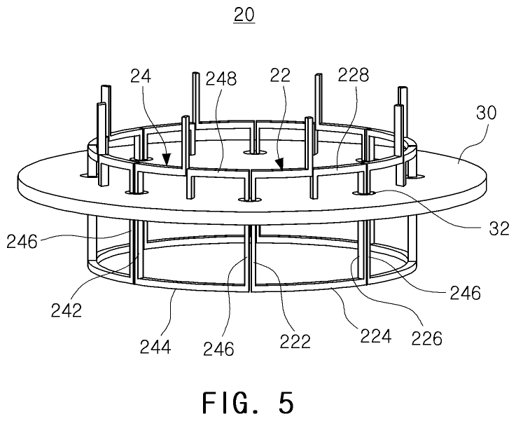

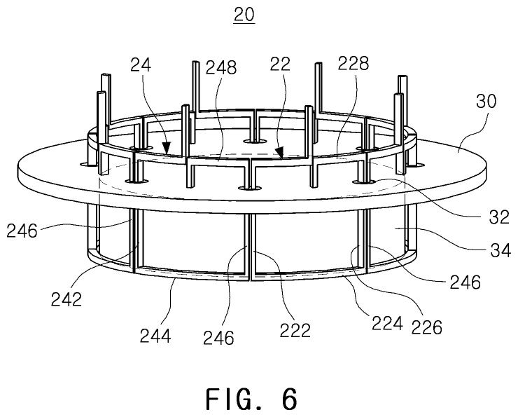

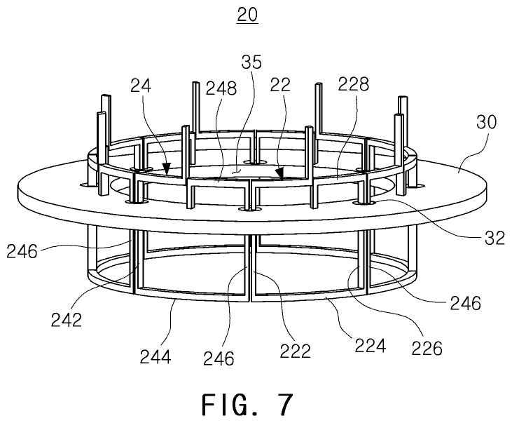

FIG. 5 is a schematic perspective view illustrating a first embodiment of the inductively coupled plasma antenna of the present inventive concept, and FIG. 6 is a schematic perspective view illustrating a second embodiment of the inductively coupled plasma antenna of the present inventive concept. Additionally, FIG. 7 is a schematic perspective view illustrating a third embodiment of the inductively coupled plasma antenna of the present inventive concept. Referring to FIGS. 5 to 7, the first lines 222 and 242 and the third lines 226 and 246 penetrate through the shielding portion 30, respectively, and the shielding portion 30 is disposed between the second lines 224 and 244 and the fourth lines 226 and 246, respectively. The shielding portion 30 of the example embodiment of FIG. 5 is a metal plate and may include ferromagnetic or ferrimagnetic material.

The coils forming the first lines 222 and 242 and the third lines 226 and 246 may be simultaneously disposed within one through-hole 32 formed in the shielding portion 30 and may penetrate substantially vertically. The first line 222 of the first loop coil portion 22 and the third line 246 of the second loop coil portion 24 are very adjacent within the through-hole 32, and since the high-frequency currents flowing through the first line 222 and the third line 246 flow in opposite directions, the magnetic fields generated from the first line 222 and the third line 246 may be almost canceled.

When viewed from the shielding portion 30, the second lines 224 and 244 are placed on the lower portion of the metal plate, and the fourth lines 226 and 246 are placed on the upper portion of the metal plate. The magnetic fields generated by the high-frequency currents of the second lines 224 and 244 and the fourth lines 228 and 248 are canceled out because they flow in opposite directions, but the shielding portion 30 may significantly reduce the effect of offsetting magnetic fields generated in the second lines 224 and 244 and the fourth lines 228 and 248. Additionally, the shielding portion 30 may properly maintain the voltage of the inductively coupled plasma antenna flowing through the second lines 224 and 244. The fourth lines 228 and 248 of the first loop coil portion 22 and the second loop coil portion 24 may be connected to the high-frequency power sources 52 and 54 or to an RLC element or a ground terminal.

Meanwhile, in the shielding portion 30 of the example embodiment of FIG. 6, a ferromagnetic or ferrimagnetic shielding film 34 may be further disposed under the metal plate. By further disposing the shielding film 34 below the metal plate, the shielding portion 30 may control the canceling effect of magnetic fields generated in the second lines 224 and 244 and the fourth lines 228 and 248. Except for this, other descriptions of the shielding portion 30 of the example embodiment of FIG. 6 are substantially the same as those of FIG. 5 and are therefore omitted.

Meanwhile, the shielding portion 30 of the example embodiment of FIG. 7 forms a hole in the center 35 of the metal plate, and thus, the shielding portion 30 may control the offsetting effects of magnetic fields generated in the second lines 224 and 244 and the fourth lines 228 and 248. Except for this, other descriptions of the shielding portion of the example embodiment of FIG. 7 are substantially the same as those of FIG. 5 and are therefore omitted.

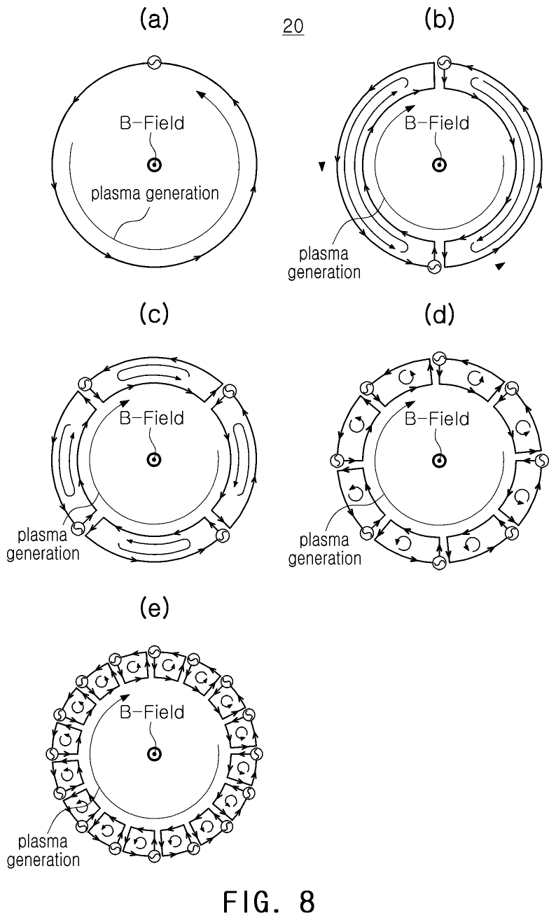

FIG. 8 is a schematic diagram illustrating current flow according to the number of segments of the inductively coupled plasma antenna of the present inventive concept. FIG. 8A illustrates that one coil of the related art independently forms a plasma, and FIGS. 8B to 8E illustrate the generation of magnetic and electric fields for plasma generation depending on the number of individual segment loop coil portions constituting the inductively coupled plasma antenna of the present inventive concept.

In FIG. 8A, as in the present inventive concept, loop antennas with different directions of high-frequency currents are adjacent to each other, so the magnetic field is canceled and the inductance cannot be reduced. The example embodiments of FIGS. 8B to 8E illustrate 2, 4, 8, and 16 individual segment loop coil portions, respectively. The example embodiments of FIGS. 8B to 8E respectively illustrate generating the electric field (EMF) necessary to form a plasma by the sum of the magnetic fields (B-field) created by the currents flowing through the individual segment loop coil portions.

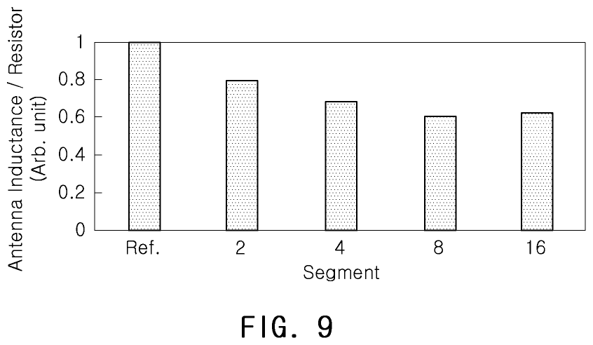

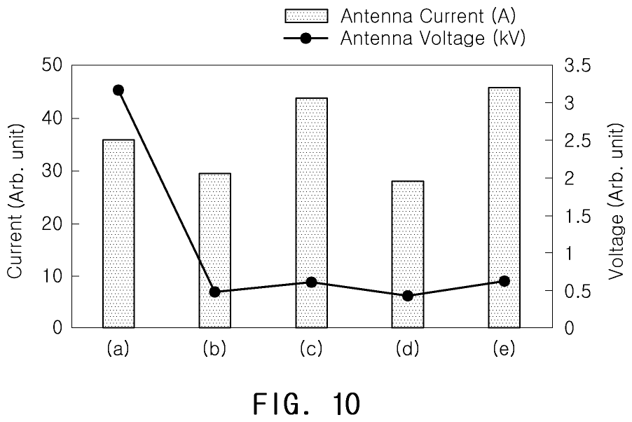

FIG. 9 is a graph illustrating the results of antenna inductance versus antenna resistance measured according to the example embodiment of FIG. 8, and FIG. 10 is a graph illustrating the measurement results of the current and voltage of the antenna measured according to the example embodiment of FIG. 8. The units of current and voltage illustrated in FIGS. 9 and 10 are arbitrary units and are current and voltage values when the same B-field (500 A/m) is formed in each embodiment.

Referring to FIG. 9, the antenna inductance compared to the antenna resistance is illustrated. It can be seen that the antenna inductance decreases in all embodiments of the present inventive concept with 2 to 16 segment loop coil portions. In the case of 8 or 16 segment loop coil portions, the antenna inductance compared to the antenna resistance may be reduced by up to 0.55 times compared to the related art technology.

Referring to FIG. 10, the magnitude of the voltage generated according to the high-frequency current may be seen. It can be seen that even when high-frequency current flows, the antenna voltage is greatly reduced compared to the prior art. In all embodiments, the antenna voltage is reduced to about 17 to 21% compared to the related art method (Ref.). This proves that even if high-frequency current is provided, the antenna inductance is reduced, and the antenna voltage is reduced due to the reduction in inductance, thereby reducing particle contamination in the process chamber.

As set forth above, with an inductively coupled plasma antenna and a semiconductor wafer processing apparatus according to some example embodiments, an inductively coupled plasma antenna with improved power loss and speed problems regardless of the use of a matcher may be provided. Furthermore, even when high-frequency power is applied, antenna inductance may be reduced, thereby reducing antenna voltage and eliminating particle contamination that may occur on a wafer in a process chamber. And, by significantly removing particle contamination from the wafer, semiconductor production yield may be improved and production costs may be lowered.

While example embodiments have been illustrated and described above, it will be apparent to those skilled in the art that modifications and variations could be made without departing from the scope of the present inventive concept as defined by the appended claims.

1. An inductively coupled plasma antenna configured for use in a semiconductor wafer processing apparatus, comprising:
a plurality of loop-shaped coil portions extending adjacent to each other in sequence, said plurality of loop-shaped coil portions including at least a first loop-shaped coil portion and a second loop-shaped coil portion; and
a high-frequency power source configured to supply high-frequency current to each of the plurality of loop-shaped coil portions, such that respective high-frequency currents flow in opposite directions in adjacent and facing lines of the first loop-shaped coil portion and the second loop-shaped coil portion.

2. The antenna of claim 1, wherein each of the first loop-shaped coil portion and the second loop-shaped coil portion respectively includes:
a first line through which a high-frequency current flows, when provided by the high-frequency power source;
a second line through which the high-frequency current flows after passing through first line, to thereby support generation of a plasma;
a third line through which the high-frequency current flows after passing through the second line, and in a direction opposite to a direction of current flow in an adjacent first line of an adjacent loop coil portion; and
a fourth line through which the high-frequency current flows in a direction opposite to a direction of current flow in the second line of the same loop coil portion.

3. The antenna of claim 2, further comprising a shielding portion through which the first line and the third line of the same loop-shaped coil portion penetrate, and which extends between the corresponding second and fourth lines.

4. The antenna of claim 3, wherein the shielding portion includes a metal plate without a hole in a center thereof or a metal plate with a hole formed in the center thereof.

5. The antenna of claim 3, wherein the shielding portion includes a metal plate, and a ferromagnetic or ferrimagnetic shielding film adjacent an underside of the metal plate.

6. The antenna of claim 3, wherein the first line of the first loop-shaped coil portion and the first line of the second loop-shaped coil portion are independently electrically connected to a corresponding high-frequency power source, or the first line of the first loop-shaped coil portion and the first line of the second loop-shaped coil portion are electrically connected in common to a connection line, which is branched from the high-frequency power source.

7. The antenna of claim 3, wherein an end of the fourth line of a respective loop-shaped coil portion is grounded to the shielding portion.

8. The antenna of claim 1, wherein the high-frequency power source is electrically connected to a synchronization device, which is configured to control a shape of the high-frequency current.

9. An inductively coupled plasma antenna configured for use in a semiconductor wafer processing apparatus, comprising:
a first loop-shaped coil portion, which includes a first line through which a high-frequency current flows, a second line through which the high-frequency current flows and generates a plasma, a third line which opposes the first line and through which the high-frequency current flows in a direction opposite to a direction of current through the first line, and a fourth line through which the high-frequency current flows in a direction opposite to a direction of current through the second line;
a second loop-shaped coil portion extending immediately adjacent the first loop-shaped coil portion, and including a first line through which a high-frequency current flows, a second line through which the high-frequency current having passed through the first line flows and generates a plasma, a third line which opposes the first line and through which the high-frequency current flows in a direction opposite to a direction of current through the first line, and a fourth line through which the high-frequency current flows in a direction opposite to a direction of current through the second line;
a high-frequency power source configured to supply respective high-frequency currents to the first loop-shaped coil portion and the second loop-shaped coil portion; and
a shielding portion having a through-hole through which the first line of the first loop-shaped coil portion and the third line of the second loop-shaped coil portion penetrate, the shielding portion being disposed between the second line and the fourth line of each of the first loop-shaped coil portion and the second loop-shaped coil portion.

10. The antenna of claim 9, wherein the third line of the first loop-shaped coil portion and the first line of the second loop-shaped coil portion extend immediately adjacent to each other with a gap therebetween; and wherein high-frequency currents in the third line of the first loop-shaped coil portion and the first line of the second loop-shaped coil portion flow in opposite directions.

11. The antenna of claim 9, wherein the shielding portion includes a metal plate with or without a hole in its center.

12. The antenna of claim 9, wherein the shielding portion includes a metal plate, and a ferromagnetic or ferrimagnetic shielding film adjacent an underside of the metal plate.

13. The antenna of claim 9, wherein the first line of the first loop-shaped coil portion and the first line of the second loop-shaped coil portion are independently electrically connected to a corresponding high-frequency power source, or the first line of the first loop-shaped coil portion and the first line of the second loop-shaped coil portion are electrically connected in common to a connection line, which is branched from the high-frequency power source.

14. The antenna of claim 9, wherein an end of the fourth line of a respective loop-shaped coil portion is grounded to the shielding portion.

15. The antenna of claim 9, wherein the high-frequency power source is electrically connected to a synchronization device, which is configured to control a shape of the high-frequency current.

16. A semiconductor wafer processing apparatus, comprising:
a process chamber having an internal space therein;
a lower electrode configured to support a semiconductor wafer within the process chamber;
an upper electrode that faces the lower electrode and includes a shower head configured to supply plasma gas; and
an inductively coupled plasma antenna including a segment coil portion in which a plurality of loop-shaped segment coils disposed on an upper portion of the upper electrode are adjacently disposed, said inductively coupled plasma antenna including a high-frequency power source electrically connected to each of the plurality of loop-shaped segment coils and individually supplying high-frequency current;
wherein the plurality of loop-shaped segment coils include a first loop-shaped coil portion and a second loop-shaped coil portion;
wherein the first loop-shaped coil portion and the second loop-shaped coil portion respectively include:
a first line through which the high-frequency current flows;
a second line through which the high-frequency current having passed through the first line flows and generates a plasma;
a third line through which the high-frequency current of which a direction has been changed through the second line flows; and
a fourth line through which the high-frequency current flows in a direction opposite to a direction of current through the second line; and
wherein the high-frequency current flowing through the first line of one of the first loop-shaped coil portion and the second loop-shaped coil portion and the high-frequency current flowing through the third line of the other, facing the first line, flow in opposite directions.

17. The apparatus of claim 16, further comprising a shielding portion having a through-hole through which the first line of the first loop-shaped coil portion and the third line of the second loop-shaped coil portion penetrate, and disposed between the second line and the fourth line of each of the first loop-shaped coil portion and the second loop-shaped coil portion.

18. The apparatus of claim 17, wherein the shielding portion includes a metal plate with or without a hole in a center thereof.

19. The apparatus of claim 18, wherein the shielding portion includes a ferromagnetic or ferrimagnetic shielding film adjacent an underside of the metal plate.

20. The apparatus of claim 16,
wherein the high-frequency power source is connected to a synchronization device that is configured to adjust a shape of the high-frequency current;
wherein the first line of the first loop-shaped coil portion and the first line of the second loop-shaped coil portion are independently electrically connected to a corresponding high-frequency power source, or the first line of the first loop-shaped coil portion and the first line of the second loop-shaped coil portion are electrically connected in common to a connection line, which is branched from the high-frequency power source.

21. (canceled)
